(19) United States
(12) Patent Application Publication
(10) Pub. No.: US 2024/0272421 A1
(43) Pub. Date: Aug. 15, 2024

(54) OPTICAL MODULE, OPTICAL ENGINE FOR IMAGE PROJECTION, AND GLASS DISPLAY

(71) Applicant: TDK CORPORATION, Tokyo (JP)

(72) Inventors: Hideaki FUKUZAWA, Tokyo (JP); Tomohito MIZUNO, Tokyo (JP); Tsuyoshi KOMAKI, Tokyo (JP); Ardalan HESHMATI, Saratoga, CA (US); Kit Chu LAM, Shanghai (CN)

(73) Assignee: TDK CORPORATION, Tokyo (JP)

(21) Appl. No.: 18/406,332

(22) Filed: Jan. 8, 2024

(30) Foreign Application Priority Data
Feb. 15, 2023 (JP) 2023-021791

(51) Int. Cl. G02B 26/10; G02B 26/08; G02B 27/01

(52) U.S. Cl. CPC G02B 26/101; G02B 26/0833; G02B 27/0172; G02B 2027/0178

(57) ABSTRACT

An optical module for displaying an image: a laser light source part with laser light emitting elements emitting laser lights having different peak wavelengths; a mirror part with an optical scanning mirror element on a second substrate integrated with the first substrate; a laser drive control part individually and independently controlling an intensity of laser light from the laser light emitting elements; a mirror drive control part controlling swinging of the optical scanning mirror element; a memory storing a lookup table that is an array of correspondence relations between each swing position of the optical scanning mirror element and a projection position of laser light from the laser light emitting elements on the image display surface; and a system control part controlling the laser drive control part and the mirror drive control part so as to control the mirror drive control part based on the lookup table.

### BACKGROUND OF THE INVENTION

### Field of the Invention

The present invention relates to an optical module, an optical engine for image projection, and a glass display.

Priority is claimed on Japanese Patent Application No. 2023-021791 filed Feb. 15, 2023, the content of which is incorporated herein by reference.

### Description of Related Art

Augmented reality (AR) glasses and virtual reality (VR) glasses are expected to be used as small wearable devices. In such devices, a light emitting element that emits full-color visible light is one of the main elements for rendering high-quality images. In such a device, a light emitting element independently and rapidly modulates the intensity of each of the three colors of RGB representing visible light, for example, to express a moving image in a desired color.

As such a light emitting element, Patent Document 1 discloses a light emitting element that emits a color moving image by causing a visible light laser to be incident on a waveguide and controlling the emission intensity of a laser chip of each color using an electric current. Furthermore, Patent Document 2 disclosures a modulator that causes laser light to be incident into an external modulator having a waveguide formed on a substrate having an electro-optic effect via an optical fiber and modulates intensity of each of three colors of RGB independently by an external modulator.

In wearable devices such as AR glasses and VR glasses, the key to their widespread use is to miniaturize the light emitting module so that each function fits within a size of a normal eyeglass. A miniaturized light emitting module that can be applied to such wearable devices is considered to have a structure in which laser light emitted from a light emitting element is directly reflected toward an image display surface (an image projection surface) by a mirror without going through a waveguide or the like. For example, Patent Document 3 discloses an optical module in which a laser light emitting element and a mirror are mounted on one common substrate.

### [Patent Documents]

[Patent Document 1] Japanese Unexamined Patent Application, First Publication No. 2021-86976

[Patent Document 2] Japanese Patent No. 6728596

[Patent Document 3] United States Patent Application, Publication No. 2020-0110331

### SUMMARY OF THE INVENTION

However, since the optical module disclosed in Patent Document 3 has a configuration in which the laser light emitting element and the mirror are provided on one common substrate and the mirror is fixed to an inclined surface formed on the substrate, it has not been possible to adjust an optical axis position of the laser light incident on the mirror after the optical module is manufactured. Therefore, when the optical module is mounted on a device, there has been a problem in that adjustment of a mounting position of the optical module in order to emit the laser light to a predetermined position on the image display surface becomes complicated (the image projection surface).

Furthermore, when a plurality of laser light emitting elements such as those of RGB are used in an optical module, relative positions between each of the laser light emitting elements and the mirror are different from each other, and thus positions at which the laser lights of each color reflected by the mirror are projected onto the image projection surface are shifted. The shift of the projection position reduces sharpness of an image as a size becomes smaller.

The present invention has been made in consideration of such circumstances, and an object thereof is to provide an optical module, an optical engine for image projection, and a glass display in which a laser light emitting element and an optical scanning mirror are mounted on a substrate, and then optical axis adjustment can be performed, and a decrease in image quality caused by a shift in a projection position of each color of laser light reflected by the mirror on an image projection surface can be compensated for.

In order to solve the above problem, the following means are provided.

A first aspect of the present invention is an optical module for displaying an image by projecting laser light onto an image display surface, including: a laser light source part provided with a plurality of laser light emitting elements on a main surface of a first substrate, each of the laser light emitting elements being configured to emit each of a plurality of laser lights having different peak wavelengths, respectively; a mirror part provided with an optical scanning mirror element on a main surface of a second substrate that is integrated with the first substrate; a laser drive control part configured to individually and independently control an intensity of laser light emitted from the laser light emitting elements; a mirror drive control part configured to control swinging of the optical scanning mirror element; a memory configured to store a lookup table that is an array of correspondence relations between each swing position of the optical scanning mirror element and a projection position of each laser light emitted from each of the laser light emitting elements on the image display surface; and a system control part configured to control the laser drive control part and the mirror drive control part, wherein the system control part controls the mirror drive control part on a basis of the lookup table.

According to a second aspect, in the optical module of the first aspect, the system control part may be configured to create a light intensity map table from image data that is a pixel value of each pixel of an image to be displayed on the image display surface and the lookup table and may be configured to control the laser drive control part and the mirror drive control part to construct the image on a basis of the light intensity map table, the light intensity map table being an intensity ratio of the laser light emitted from each of the laser light emitting elements for each swing position of the optical scanning mirror element.

According to a third aspect, in the optical module of the first or second aspect, the first substrate and the second substrate may be bonded via a metal bonding layer.

According to a fourth aspect, in the optical module of any one of the first to third aspects, the laser light emitting elements may be configured to emit visible light range laser light in a wavelength range of 380 nm or more and less than 800 nm.

According to a fifth aspect, in the optical module of any one of the first to fourth aspects, the optical scanning mirror element may be a MEMS mirror.

According to a sixth aspect, in the optical module of any one of the first to fifth aspects, a surface of a mirror surface portion of the optical scanning mirror element may be a concave mirror of which a cross section passing through a center point forms a parabola.

A seventh aspect of the present invention is an optical engine for image projection, including the optical module of any one of the first to sixth aspects, one common substrate on which the first substrate and the second substrate are placed; and an integrated circuit formed on the common substrate and configured to control the laser light emitting element and the optical scanning mirror element.

An eighth aspect of the present invention is a glass display including the optical engine for image projection of the seventh aspect, and a frame having an eyeglass shape, wherein the optical engine for image projection is disposed at a temple part of the frame.

According to the present invention, it is possible to provide an optical module in which each of a laser light emitting element and an optical scanning mirror is mounted on a substrate, and then optical axis adjustment can be performed, and a decrease in image quality caused by a shift in a projection position of each color of laser light reflected by the mirror on an image projection surface can be compensated for.

### BRIEF DESCRIPTION OF THE DRAWINGS

FIG. 1 is an external perspective view showing an optical module according to a first embodiment of the present invention.

FIG. 2 is a schematic cross-sectional view of the optical module shown in FIG. 1.

FIG. 3A is a diagram conceptually describing a compensation method due to software control of image quality.

FIG. 3B is a diagram conceptually describing a compensation method due to software control of image quality (Step 1).

FIG. 4 is a diagram for describing the compensation method due to software control of the image quality.

FIG. 5A is a diagram for describing the compensation method due to the software control of the image quality (Step 3, T=t1).

FIG. 5B is a diagram for describing the compensation method due to the software control of the image quality (Step 3, T=t2).

FIG. 5C is a diagram for describing the compensation method due to the software control of the image quality (Step 3, T=t3).

FIG. 6 is a diagram for describing the compensation method due to the software control of the image quality.

FIG. 7 is a diagram for describing the compensation method due to the software control of the image quality.

FIG. 8 is a diagram conceptually describing the optical module of the present invention.

FIG. 9 is a schematic diagram showing an action of an optical scanning mirror element having a concave mirror.

FIG. 10 is a schematic diagram showing an action of an optical scanning mirror element with another configuration having a concave mirror.

FIG. 11 is a flowchart showing a method for manufacturing the optical module of this embodiment in a stepwise manner.

FIG. 12 is an external perspective view showing an optical module according to a second embodiment of the present invention.

FIG. 13 is an external perspective view showing an optical engine for image projection according to an embodiment of the present invention.

FIG. 14 is an enlarged perspective view of a main part of a glass display according to an embodiment of the present invention.

### DETAILED DESCRIPTION OF THE INVENTION

Hereinafter, embodiments will be described in detail with reference to drawings as appropriate. In the drawings used in the following description, characteristic parts may be shown enlarged for convenience in order to make the characteristics easier to understand, and a dimensional ratio of each component may differ from actual one. Materials, dimensions, and the like exemplified in the following description are merely examples, and the present invention is not limited thereto and can be implemented with appropriate changes within the scope of achieving effects of the present invention.

### [Optical Module (First Embodiment)]

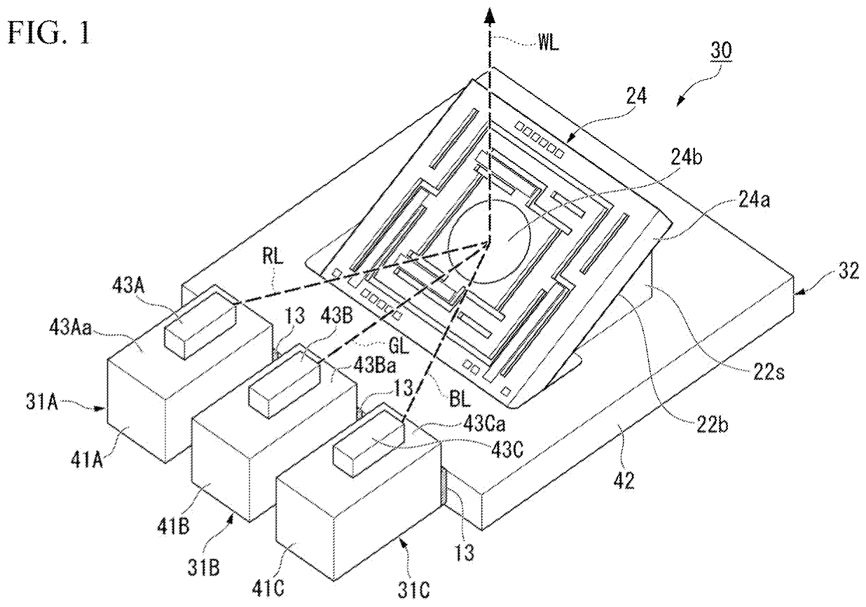

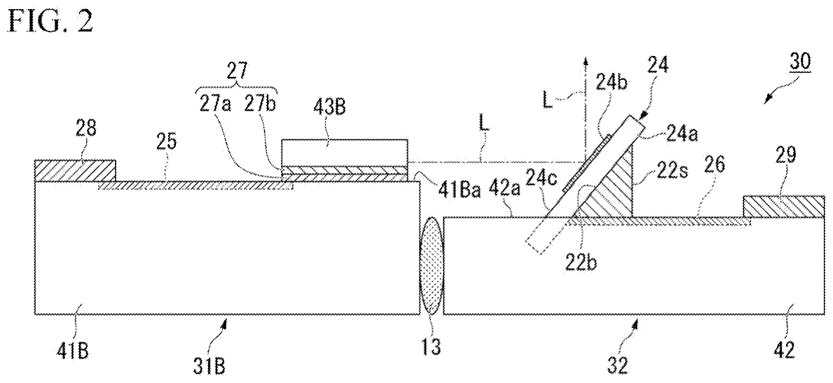

FIG. 1 is an external perspective view showing an optical module according to a first embodiment of the present invention. Moreover, FIG. 2 is a cross-sectional view of the optical module shown in FIG. 1. In FIG. 1, a case in which there are three laser light emitting elements is described, but the number is not limited to three and may be two or four or more.

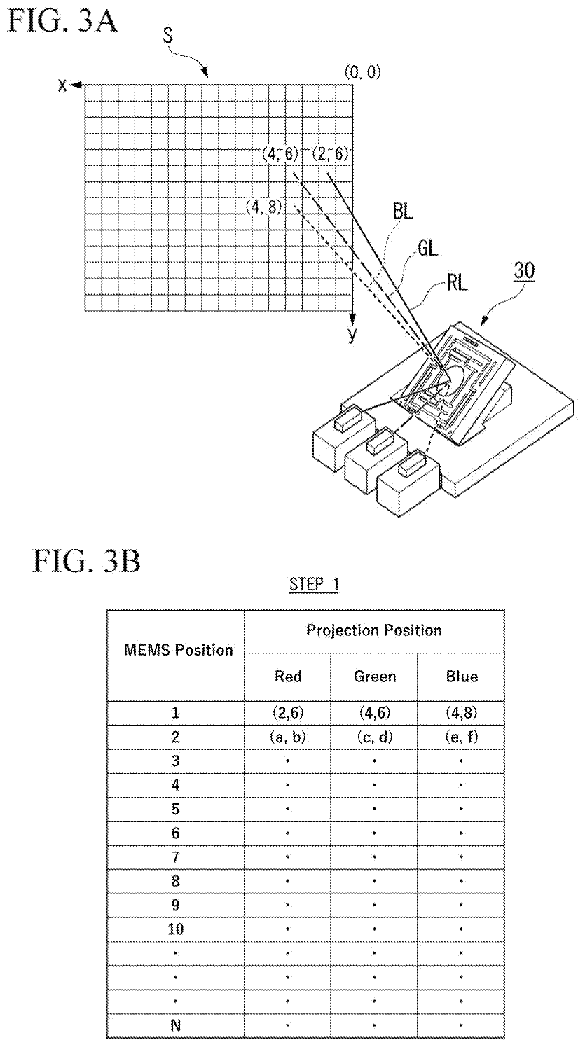

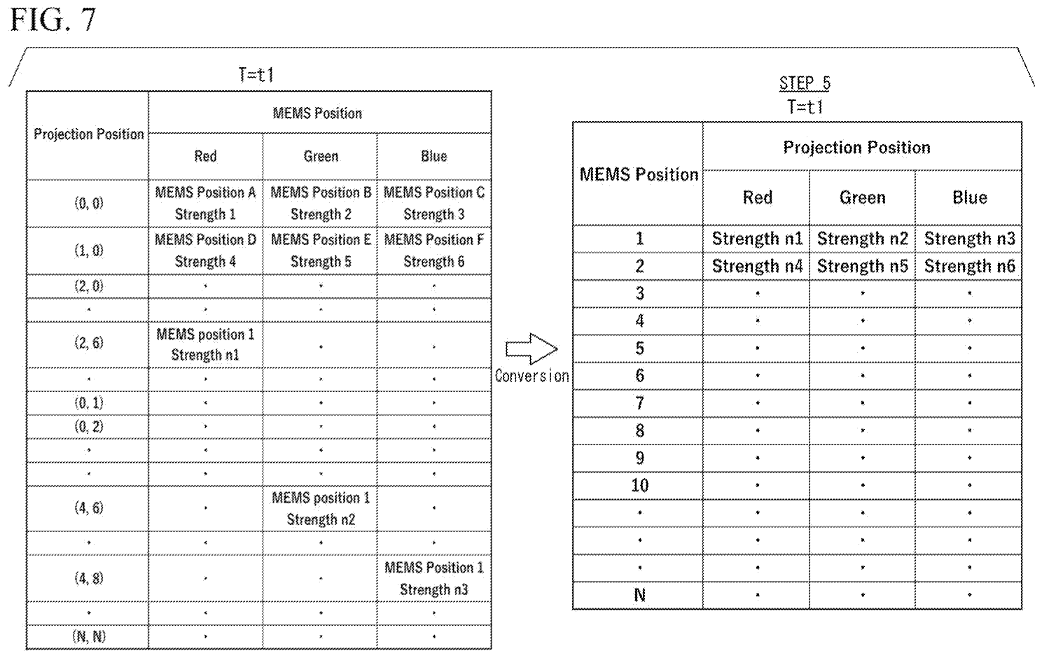

The optical module 30 according to the first embodiment is an optical module that can be used to display an image by projecting laser light onto an image display surface, and includes laser light source parts 31A, 31B, and 31C in which a plurality of laser light emitting elements 43A, 43B, and 43C that respectively emit a plurality of laser lights having different peak wavelengths are provided on main surfaces of first substrates 41A, 41B, and 41C, a mirror part 32 in which an optical scanning mirror element 24 is provided on a main surface of a second substrate 42 that is integrated with the first substrates 41A, 41B, and 41C, a laser drive control part 200 (refer to FIG. 8) capable of individually and independently controlling an intensity of laser light emitted from each of the plurality of laser light emitting elements 43A, 43B, and 43C, a mirror drive control part 100 (refer to FIG. 8) that controls swinging of the optical scanning mirror element 24, a memory 300 (refer to FIG. 8) that stores a lookup table which is an array of correspondence relationships between each swing position of the optical scanning mirror element 24 and a projection position on an image display surface S (refer to FIG. 3A and FIG. 3B) for each laser light emitted from each of the plurality of laser light emitting elements 43A, 43B, and 43C, and a system control part 400 (refer to FIG. 8) that creates a light intensity map table, which is an intensity ratio of the laser light emitted from each of the plurality of laser light emitting elements 43A, 43B, and 43C, for each swing position of the optical scanning mirror element 24 from the lookup table and image data which is a pixel value of each pixel of an image to be displayed on the image display surface S, and controls the laser drive control part 200 and the mirror drive control part 100 so as to construct an image on the basis of the light intensity map table.

The optical module 30 shown in FIG. 1 has a configuration in which each of the first substrates (first subcarriers) 41A, 41B, and 41C provided with three laser light source parts 31A, 31B, and 31C, respectively, is bonded to a second substrate (a second subcarrier) 42 provided with one mirror part 32 via a metal bonding layer 13.

The first substrates 41A, 41B, and 41C are configured of a silicon (Si) substrate, an aluminum oxide (Al₂O₃) substrate, an aluminum nitride (AlN) substrate, a quartz (SiO₂) substrate, or the like. The first substrates 41A, 41B, and 41C may be made of the same material as the second substrate 42 constituting the mirror part 32, or may be made of a different material from the second substrate 42.

Various laser elements can be used as the laser light source part. For example, commercially available laser diodes (LDs) emitting red light, green light, blue light, and the like can be used. As the red light, light having a peak wavelength of 610 nm or more and 750 nm or less can be used, as the green light, light having a peak wavelength of 500 nm or more and 560 nm or less can be used, and as the blue light, light having a peak wavelength of 435 nm or more and 480 nm or less can be used.

The laser light emitting element 43A that constitutes the laser light source part 31A is configured of, for example, a red LD that emits red laser light RL. Further, the laser light emitting element 43B that constitutes the laser light source part 31B is configured of, for example, a green LD that emits green laser light GL. Furthermore, the laser light emitting element 43C that constitutes the laser light source part 31C is configured of, for example, a blue LD that emits blue laser light BL.

The laser light emitting elements 43A, 43B, and 43C are respectively bonded to the first substrates 41A, 41B, and 41C via a metal layer 27, for example. The metal layer 27 may be configured of two metal layers including, for example, a first metal layer 27a and a second metal layer 27b. Such a metal layer 27 can be formed by a known method such as sputtering, vapor deposition, or application of a metal paste.

The first metal layer 27a may be made of, for example, an alloy of gold (Au) and tin (Sn), an alloy of tin (Sn) and copper (Cu), an alloy of indium (In) and bismuth (Bi), a tin (Sn)-silver (Ag)-copper (Cu) based solder alloy (SAC), or the like. The second metal layer 27b may be made of, for example, gold (Au), platinum (Pt), silver (Ag), lead (Pb), indium (In), nickel (Ni), or the like.

A first wiring layer 25 of which one end side is connected to the laser light emitting elements 43A, 43B, and 43C is formed on main surfaces 41Aa, 41Ba, and 41Ca of the first substrates 41A, 41B, and 41C. The first wiring layer 25 is an electric wiring for supplying a driving current to the laser light emitting elements 43A, 43B, and 43C, and may be a pattern wiring formed by forming a metal thin film made of gold, silver, aluminum, or the like in a predetermined pattern, for example. A first electrode (an electrode pad) 28 may be formed on the other end side of the first wiring layer 25. The first electrode (the electrode pad) 28 is connected to, for example, an external drive power source or a control integrated circuit.

The mirror part 32 includes a second substrate (a subcarrier) 42 and an optical scanning mirror element 24 formed on a main surface 42a of the second substrate 42.

The second substrate 42 is configured of a silicon (Si) substrate, an aluminum oxide (Al₂O₃) substrate, an aluminum nitride (AlN) substrate, a quartz (SiO₂) substrate, or the like. The second substrate 42 has an inclined part 22s having an inclined surface 22b inclined at a predetermined angle, for example, 45 degrees, with respect to the main surface 42a.

The inclined part 22s is formed so that a part of the inclined surface 22b extends to a deeper position in a thickness direction than the main surface 42a. The optical scanning mirror element 24 is placed on the inclined surface 22b of the inclined part 22s. An angle of inclination of the inclined surface 22b with respect to the main surface 42a may be within a range of, for example, 10° to 70°.

The optical scanning mirror element (a MEMS mirror) 24 is, for example, a micro electro mechanical system (MEMS) device obtained by finely processing a silicon wafer. The optical scanning mirror element 24 of this embodiment includes a mirror surface portion 24b having a circular shape and disposed at the center of a base body 24a, a beam portion 24c that supports the mirror surface portion 24b, and an application electrode (not shown) that bends the beam portion 24c. A surface (a reflection surface) of the mirror surface portion 24b is, for example, formed in a planar shape. Although the mirror surface portion 24b is formed in a circular shape in this embodiment, it is not limited to a circular shape, and may be formed in any shape, such as a rectangular or polygonal shape.

Such an optical scanning mirror element 24 generates an electrostatic force by applying a predetermined voltage to the application electrode. Then, the beam portion 24c is locally bent according to a position at which the electrostatic force is generated, thereby changing an angle of the mirror surface portion 24b supported by the beam portion 24c two-dimensionally (a horizontal direction (an X direction) and a vertical direction (a Y direction)). A reflection angle of the laser light L reflected by the mirror surface portion 24b is changed by changing the angle of the mirror surface portion 24b. That is, due to the laser light L being scanned from the mirror surface portion 24b, arbitrary characters or figures can be displayed on the display surface by the laser light L.

A second wiring layer 26 of which one end side is connected to the optical scanning mirror element 24 is formed on the main surface 42a of the second substrate 42.

The second wiring layer 26 is an electric wiring for supplying a drive current that changes an angle of the mirror surface portion 24b of the optical scanning mirror element 24, and may be a pattern wiring formed by forming a metal thin film made of gold, silver, aluminum, or the like in a predetermined pattern, for example. A second electrode (an electrode pad) 29 may be formed on the other end side of the second wiring layer 26. The second electrode (the electrode pad) 29 is connected to, for example, an external drive power source or a control integrated circuit.

The laser light source parts 31A, 31B, and 31C and the mirror part 32 are disposed adjacent to each other. The first substrates 41A, 41B, and 41C constituting the laser light source parts 31A, 31B, and 31C and the second substrate 42 constituting the mirror part 32 are directly bonded to each other via the metal bonding layer 13. That is, the laser light source parts 31A, 31B, and 31C and the mirror part 32 are integrated by the metal bonding layer 13 and constitute the optical module 30.

The metal bonding layer 13 is made of a metal material that can be bonded to the constituent material of the first substrates 41A, 41B, and 41C, the constituent material of the second substrate 42, for example, a metal material containing at least gold or tin. More specifically, as gold-based solder materials, a gold-tin solder (Au—Sn), a gold-germanium solder (Au—Ge), a gold-silicon solder (Au—Si), and the like may be used. Further, as tin-based solder materials, an eutectic solder (Sn—Pb), a lead-free solder (Sn—Ag), a copper-tin solder (Sn—Cu), or the like may be used. The constituent material of the metal bonding layer 13 may be appropriately selected according to the constituent materials of the first substrates 41A, 41B, and 41C and the second substrate 42.

The metal bonding layer 13 is not limited to one layer. For example, when the first substrates 41A, 41B, and 41C and the second substrate 42 are made of different materials, the first substrates 41A, 41B, and 41C and the second substrate 42 may also be bonded to each other by a two-layer metal bonding layer using a metal material that is optimal for bonding the respective substrate materials. Alternatively, three or more metal bonding layers can be formed using different materials.

### (Method of Compensating for Image Quality Due to Differences in Relative Position Between Each of Laser Light Emitting Elements and Optical Scanning Mirror Element by Software Control)

FIG. 3A and FIG. 3B are a schematic diagram conceptually showing shift in a projection position of each color on the image display surface (the image projection surface) due to a difference in relative position of each of R, G, and B lasers and a MEMS mirror. A method of compensating for image quality due to the shift by software control will be described using FIGS. 3 to 8. Although a MEMS mirror will be described below as an example of the optical scanning mirror element, it is not limited to the MEMS mirror, and any known optical scanning mirror element that can reflect and scan laser light can be used.

As shown in FIG. 3A and FIG. 3B, since the relative positions of the R, G, and B lasers and the MEMS mirror differ for each color laser, even when the swing position of the MEMS mirror is the same, the projection position of the laser light on the image projection surface S differs for each color. This is the same at all swing positions of the

MEMS mirrors. In FIG. 3A and FIG. 3B, the RL, GL, and BL are red laser light, green laser light, and blue laser light, respectively.

### (Step 1)

Therefore, in Step 1, a lookup table that shows the correspondence relation between each of the swing positions of the MEMS mirror and the projection position of each color of the R, G, and B lasers at all the swing positions 1 to N within a movable range of the MEMS mirror is constructed.

On the image projection surface S, a position of each pixel of an image to be displayed is expressed by coordinates (x, y). The coordinates represent the projection position of each laser light.

For example, at a swing position 1 of the MEMS mirror, the red laser light is projected onto a projection position coordinates (2,6), the green laser light is projected onto a projection position coordinates (4,6), and the blue laser light is projected onto a projection position coordinates (4,8). Furthermore, at a swing position 2, the red laser light is projected onto a projection position coordinates (a, b), the green laser light is projected onto a projection position coordinates (c, d), and the blue laser light is projected onto a projection position coordinates (e, f).

### (Step 2)

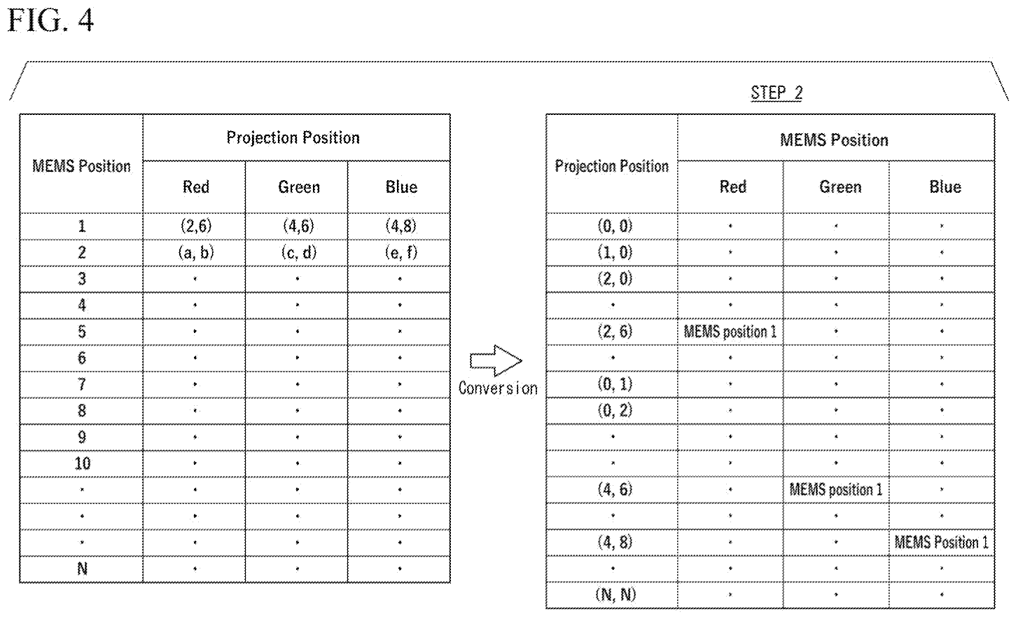

In Step 2, as shown in FIG. 4, the correspondence relation between each of the projection positions (the projection position coordinates) on the projection surface and the swing position of the MEMS mirror for each color of the R, G, and B lasers is derived by inversely converting this relationship based on the lookup table of the correspondence relation between each of the swing positions of the MEMS mirror and the projection position of each color of R, G, and B lasers obtained in Step 1. From FIG. 4, it can be understood that when it is desired to project the red laser light onto the projection position (2, 6), the swing position of the MEMS mirror should be set to the swing position 1. Similarly, it can be seen that when it is desired to project the green laser light to the projection position (4, 6), the swing position of the MEMS mirror should be set to swing position 1. It can be understood that when it is desired to project the blue laser light onto the projection position (4, 8), the swing position of the MEMS mirror should be set to the swing position 1.

### (Step 3)

In Step 3, image data is read into a memory (reference numeral 30 in FIG. 8).

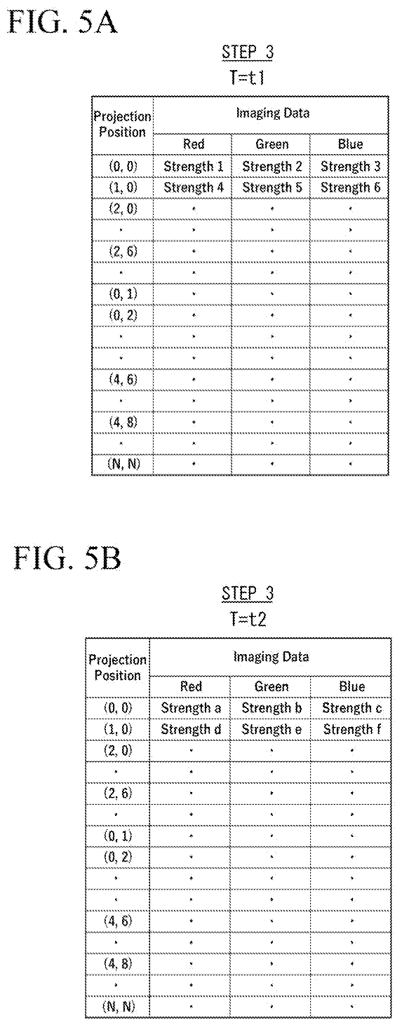

In the case of video data, as shown in FIG. 5A, FIG. 5B and FIG. 5C, it is a data group that has information on a ratio of the intensity of each color of the R, G, and B at each pixel position at each time T (t1, t2, and t3). The data group is read into the memory as the image data.

For example, in the image data of the video when T=t1, a pixel at pixel position coordinates (0,0) has an intensity (a pixel value) 1 for red, has an intensity (a pixel value) 2 for green, and has an intensity (a pixel value) of 3 for blue, and a pixel at pixel position coordinates (1, 0) has an intensity (a pixel value) of 4 for red, has an intensity (a pixel value) of 5 for green, and has an intensity (a pixel value) of 6 for blue.

Similarly, in the image data of the video when T=t2, the pixel at the pixel position coordinates (0,0) has an intensity (a pixel value) of a for red, has an intensity (a pixel value) of b for green, and has an intensity (a pixel value) of c for blue, and the pixel at the pixel position coordinates (1, 0) has an intensity (a pixel value) of d for red, an intensity (a pixel value) of e for green, and an intensity (a pixel value) of f for blue.

Similarly, in the image data of the video when T=t3, the pixel at pixel position coordinates (0,0) has an intensity (a pixel value) of i for red, has an intensity (a pixel value) of ii for green, and has an intensity (a pixel value) of iii for blue, and the pixel at the pixel position coordinates (1, 0) has an intensity (a pixel value) of iv for red, an intensity (a pixel value) of v for green, and an intensity (a pixel value) of vi for blue.

### (Step 4)

In Step 4, at each time T, an intensity map for each color of the R, G, and B lasers at each of the projection positions (the coordinates) and at each of the swing positions of the MEMS mirror are obtained by matching the correspondence relation between the image data at each time T supplied in Step 3 and the swing position of the MEMS mirror for each color of the R, G and B lasers corresponding to each of the projection positions (the coordinates) obtained in Step 2.

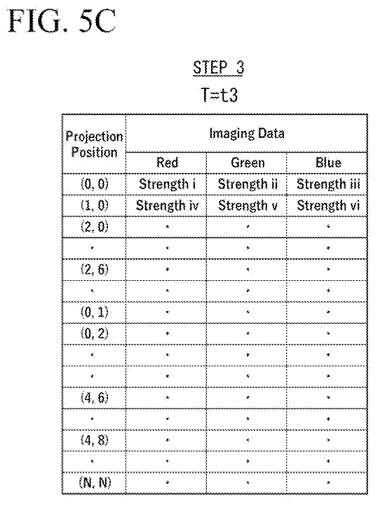

FIG. 6 shows an intensity map when T=t1.

From the intensity map in FIG. 6, in order to create a pixel (a pixel with an intensity (a pixel value) of 1 for red, an intensity (a pixel value) of 2 for green, and an intensity (a pixel value) of 3 for blue) at the pixel position (0,0) of the image (data) when T=t1 at the projection position (0,0) on the image projection surface, the intensity of the red laser light is set to the intensity of 1 with the swing position of the MEMS mirror set to a swing position A, the intensity of the green laser light is set to the intensity of 2 with the swing position of the MEMS mirror set to a swing position B, and the intensity of the blue laser light is set to an intensity of 3 with the swing position of the MEMS mirror set to a swing position C.

Similarly, in order to create a pixel (a pixel with an intensity (a pixel value) of 4 for red, an intensity (a pixel value) of 5 for green, and an intensity (a pixel value) of 6 for blue) at the pixel position (1,0) of the image (data) when T=t1 at the projection position (1,0) on the image projection surface, the intensity of the red laser light is set to the intensity of 4 with the swing position of the MEMS mirror set to a swing position D, the intensity of the green laser light is set to the intensity of 5 with the swing position of the MEMS mirror set to a swing position E, and the intensity of the blue laser light is set to the intensity of 6 with the swing position of the MEMS mirror set to a swing position F.

Similarly, in order to create a pixel (an intensity (a pixel value) of each of the

RGB not shown) at a pixel position (2,6) of the image (data) when T=t1 at a projection position (2,6) on the image projection surface, the intensity of the red laser light is set to the intensity of 1 with the swing position of the MEMS mirror set to a swing position 1, and the intensity of the green laser light and the swing position of the MEMS mirror at that time, and the intensity of the blue laser light and the swing position of the MEMS mirror at that time are not shown, but the pixel at the pixel position (2,6) of the image (data) when T=t1 can be created in the same way.

### (Step 5)

In Step 5, an intensity map table of each color laser at each of the swing positions of the MEMS mirror is obtained by inversely converting the correspondence relation between each of the pixel positions obtained in Step 4 and the intensity of each color laser at each of the swing positions of the MEMS mirror. Here, since it takes a considerable amount of time to scan the swing positions of the MEMS mirror from 1 to N, but they are scanned at a speed that is fast enough that the human eye cannot follow it, for example, about 100 to 500 MHz (a speed that is fast enough to switch the entire image 60 times per second), it is recognized as data at the same time of T=t1 (that is, it is recognized as one image).

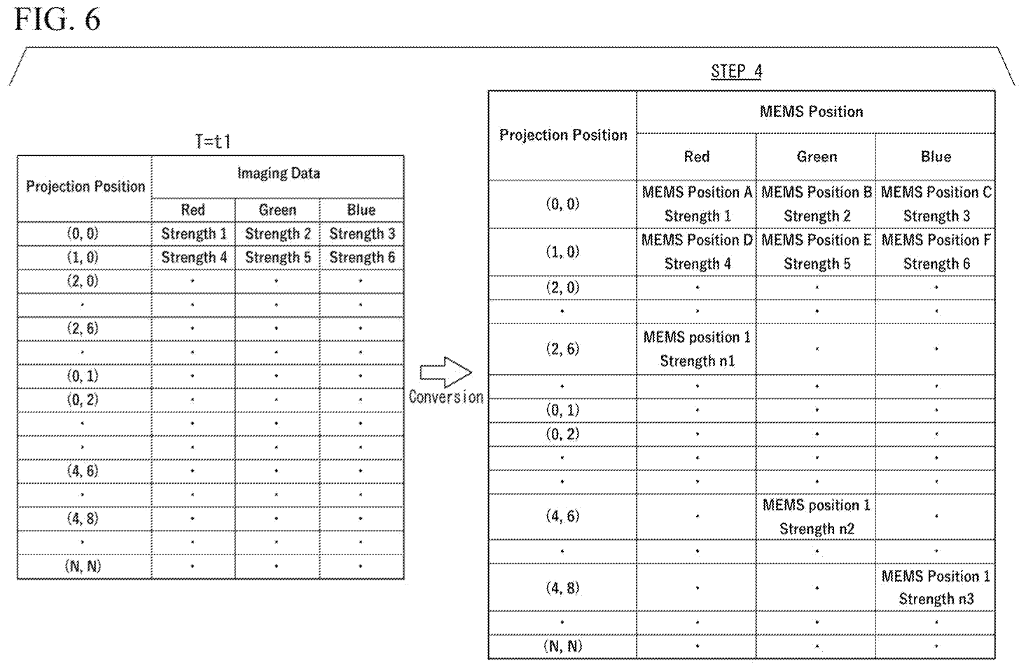

FIG. 7 shows an intensity map table of the laser when T=t1.

### (Step 6)

In Step 6, images at each time point (T =t1, t2, t3, . . . ) are projected onto the image projection surface based on the intensity map table of each color laser at each of the swing positions of the MEMS mirror obtained in Step 5.

In the case in which an image (data) is intended to be displayed based on the intensity map table of the laser shown in FIG. 7, when T=t1, with the swing position of the MEMS mirror set to the swing position 1, the intensity of the red laser light is set to an intensity of n1, the intensity of the green laser light is set to an intensity of n2, and the intensity of the blue laser light is set to an intensity of n3, then, with the swing position of the MEMS mirror set to the swing position 2, the intensity of the red laser light is set to an intensity of n4, the intensity of the green laser light is set to an intensity of n5, and the intensity of the blue laser light is set to an intensity of n6, . . . with the swing position of the MEMS mirror set to a swing position N, the intensity of the red laser light is set to an intensity according to the intensity map table, the intensity of the green laser light is set to an intensity according to the intensity map table, and the intensity of the blue laser light is set to an intensity according to the intensity map table. That is, the image is recognized to the human eye as one frame image at the same time point T=t1 by controlling the intensity of the laser light of each color of the RGB based on the intensity map table at each of the swing positions while sequentially moving the swing position of the MEMS mirror. Similarly, when T=t2, the image is recognized to the human eye as one frame image at the same time point T=t2 by controlling the intensity of the laser light of each color of the RGB based on the intensity map table at each swing position while sequentially moving the swing position of the MEMS mirror.

Specifically, as shown in FIG. 8, a mirror drive control part (IC) 100 of the MEMS mirror controls the swing position of the MEMS mirror, and the intensity of the R, G, and B lasers for each color at each of the swing positions is controlled by a laser drive control part (IC) 200, and thus the intensity of the laser is adjusted. A video controller (a system control part) 400 that controls the mirror drive control part 100 and the laser drive control part 200 is included.

Since Steps 1 and 2 are fixed when the relationship between the MEMS mirror and the projection position is determined, it is also possible to obtain the correspondence relation in advance, to create the lookup table in advance, and then to store it in the memory of the projection system.

In Steps 3 to 5, it is necessary to perform software processing based on the image data. This may be done in advance when the image data is known in advance.

Furthermore, when images are provided in real time, such as live data, they can be processed in real time at a sufficiently high speed by on-site computer processing.

Step 6 can be controlled via a drive integrated circuit (a driver IC) as actual driving.

In Step 6, although the situation in a snapshot at T=t1 has been described, in the case of a video, it is possible to display the video by performing similar processing at each time T=t2, t3, . . . .

In the above-described method of compensating for image quality by software control, the laser lights of RGB are projected at different projection positions (pixel positions) on the image projection surface at each of the swing positions of the MEMS mirror. Therefore, even when the MEMS mirror is swung monotonically, the scanning of the image projection surface with the laser light depends on the relative positional relationship between each of the RGB laser elements and the MEMS mirror.

In addition, in the above-described method of compensating for image quality by software control, although a method of compensating for the shift of the projection position of each color on the image projection surface due to the difference in relative positions of the R, G, and B lasers and the MEMS mirror only by software control has been described, but the method may be used in combination with compensation by an optical component.

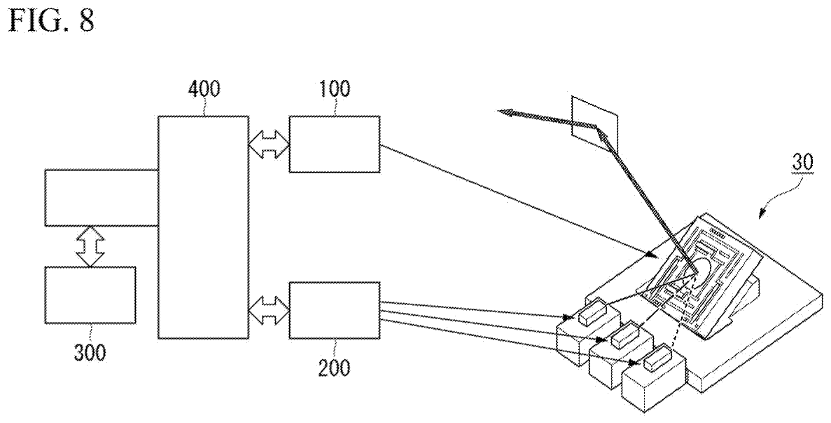

Traveling directions of the laser lights RL, GL, and BL emitted from the laser light source parts 31A, 31B, and 31C which have different laser light emission positions can be aligned, for example, using a MEMS mirror 24 as shown in FIG. 9 of which a mirror surface portion 24b has a concave reflecting surface (a concave mirror).

In particular, as shown in FIG. 9, when the MEMS mirror 24 is a concave mirror of which a cross section passing through the center of the mirror surface portion 24b forms a parabola, laser lights RL, GL, and BL that are incident at mutually different angles can be reflected as parallel lights that are parallel to each other.

Thus, even when the respective emission positions of the laser lights RL, GL, and BL are different, as long as a physical distance and positional relationship of the projection position of the mirror surface portion 24b are fixed, it is possible to radiate the laser lights RL, GL, and BL that are parallel to each other toward any one region.

However, even in such case, when a concave mirror having a parabolic shape is not ideal from a cost perspective, or the like, it is possible to further improve image quality by combining the above-described compensation method by software control.

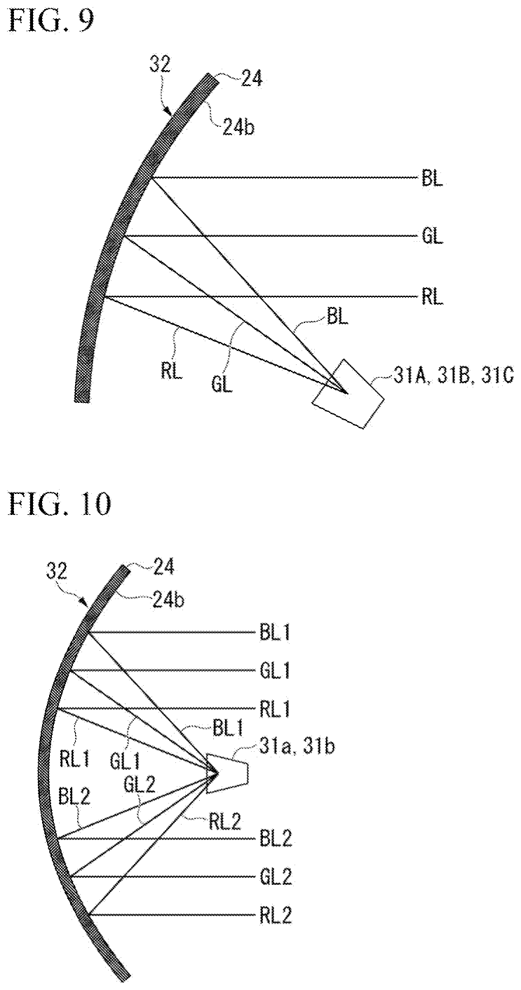

FIG. 10 shows a modified example of the MEMS mirror shown in FIG. 9.

As shown in FIG. 10, when the MEMS mirror 24 is a concave mirror of which a cross section passing through the center of the mirror surface portion 24b forms a parabola, it is also possible to adopt a configuration in which two sets of three R, G, and B laser light source parts are provided, and three laser lights RL1, GL1, and BL1 are emitted from one set of laser light source parts 31a and are reflected at a region near the center of the mirror surface portion 24b, three laser lights RL2, GL2, and BL2 are emitted from the other set of laser light source parts 31b and are reflected at another region near the center of the mirror surface portion 24b.

Thus, two sets of mutually parallel RGB laser lights consisting of mutually parallel laser lights RL1, GL1, and BL1, and RL2, GL2, and BL2 can be radiated on an external display surface or the like.

Even in the case of this configuration, it is possible to further improve the image quality by combining the above-described compensation method by software control.

### [Method for Manufacturing Optical Module]

A method for manufacturing the optical module of this embodiment will be described.

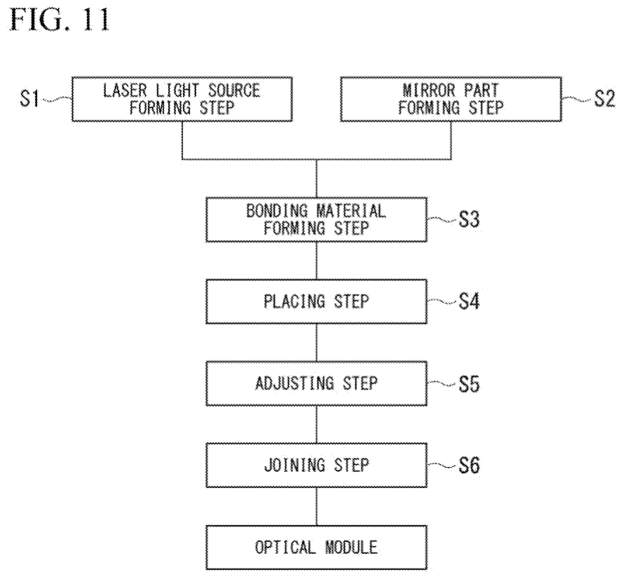

FIG. 11 is a flowchart showing the method for manufacturing the optical module of this embodiment in a stepwise manner.

When the optical module 30 of this embodiment is manufactured, first, the laser light emitting elements 43A, 43B, and 43C are bonded to the main surfaces 41Aa, 41Ba, and 41Ca of the first substrates 41A, 41B, and 41C via the metal layer 27. Further, the first wiring layer 25 and the first electrode 28 are formed on the main surfaces 41Aa, 41Ba, and 41Ca of the first substrates 41A, 41B, and 41C. Thus, the laser light source parts 31A, 31B, and 31C are obtained (laser light source part forming step S1).

Further, the optical scanning mirror element 24 is bonded to the inclined surface 22b of the inclined part 22s constituting the second substrate 42, for example, via an adhesive layer. Further, the second wiring layer 26 and the second electrode 29 are formed on the main surface 42a of the second substrate 42. Thus, the mirror part 32 is obtained (mirror part forming step S2).

Next, a bonding material made of the constituent material of the metal bonding layer 13 is dipped into at least one or both of the end surfaces of the first substrates 41A, 41B, and 41C forming the laser light source parts 31A, 31B, and 31C and the second substrate 42 forming the mirror part 32. In this embodiment, the bonding material is dipped into the end surface of the second substrate 42 constituting the mirror part 32 (bonding material forming step S3).

Next, the laser light source parts 31A, 31B, and 31C and the mirror part 32 are placed (temporarily placed) adjacent to each other with the bonding material interposed therebetween (placing step S4).

Next, a power source is connected to the laser light emitting elements 43A, 43B, and 43C via the first wiring layer 25 to drive the laser light emitting elements 43A, 43B, and 43C, and the laser light L is radiated toward the mirror surface portion 24b of the optical scanning mirror element 24 constituting the mirror part 32. Further, the laser light L reflected by the mirror surface portion 24b is made incident on an optical detection device, for example, a photodetector. Then, in this state, the end surfaces of the first substrates 41A, 41B, and 41C and the second substrate 42 are brought closer to each other, and the relative positions of the laser light source parts 31A, 31B, and 31C and the mirror part 32 are adjusted with reference to measured values of the photodetector so that an optical axis of the laser light L is aligned with a center position of the mirror surface portion 24b of the optical scanning mirror element 24 (adjusting step S5).

Then, at the positions adjusted in the adjusting step S5, heat rays are radiated toward the end surface of the second substrate 42 to melt the bonding material. Then, the end surfaces of the first substrates 41A, 41B, and 41C and the second substrate 42 are bonded to each other via the metal bonding layer 13 formed by cooling and solidifying the melted bonding materials (joining step S6). The heat rays used in the joining step S6 may be, for example, solid laser light mainly having a wavelength of 1064 μm emitted from a YAG laser device.

Through the steps described above, the optical module 30 of this embodiment can be manufactured. According to the optical module 30 of this embodiment, since the substrates (the first substrates 41A, 41B, and 41C) on which the laser light emitting elements 43A, 43B, and 43C are placed, and the substrate (the second substrate 42) on which the optical scanning mirror element 24 is placed are separate substrates, and the substrates are bonded to each other via the metal bonding layers 13, during manufacturing, the relative positions of the first substrates 41A, 41B, and 41C and the second substrate 42 are adjusted, and alignment of the optical axis position of the laser light L can be performed so that the optical axis of the laser light L can be aligned with the center position of the mirror surface portion 24b of the optical scanning mirror element 24 (active alignment). Thus, for example, compared to a conventional optical module in which a laser light emitting element and a mirror element are mounted on one common substrate, it is possible to obtain the optical module 30 that can radiate the laser light L maintaining a strong light quantity with high positional accuracy.

Further, since the substrates (the first substrates 41A, 41B, and 41C) on which the laser light emitting elements 43A, 43B, and 43C are placed and the substrate (the second substrate 42) on which the optical scanning mirror element 24 is placed are configured as mutually separate substrates, the optical module can be easily manufactured.

According to the optical module 30 obtained in this way, when the laser light source parts 31A, 31B, and 31C are scanned at arbitrary timings, an image of any color tone, for example, a full color image, can be displayed on an external display surface by the laser light WL reflected by the mirror surface portion 24b of the optical scanning mirror element 24.

Furthermore, in the optical module 30, each of the first substrates 41A, 41B, and 41C is bonded to one second substrate 42 via the metal bonding layer 13, and thus when the optical module 30 is manufactured, the optical axis positions of the laser light source parts 31A, 31B, and 31C and the optical scanning mirror element 24 can be aligned with each other (active alignment). Therefore, it is possible to accurately focus the three laser lights RL, GL, and BL toward the center of the mirror surface portion 24b of the optical scanning mirror element 24, and thus to display a clear, blur-free and full-color image on an external display surface.

Further, according to the optical module 30, since the laser lights emitted from the laser light source parts 31A, 31B, and 31C are directly focused on the center of the mirror surface portion 24b of the optical scanning mirror element 24, as in the related art, an optical waveguide unit for coupling a plurality of laser lights or the like is not required, and it is possible to realize an optical module 30 that is compact and lightweight and is compatible with full-color images.

### [Optical Module (Second Embodiment)]

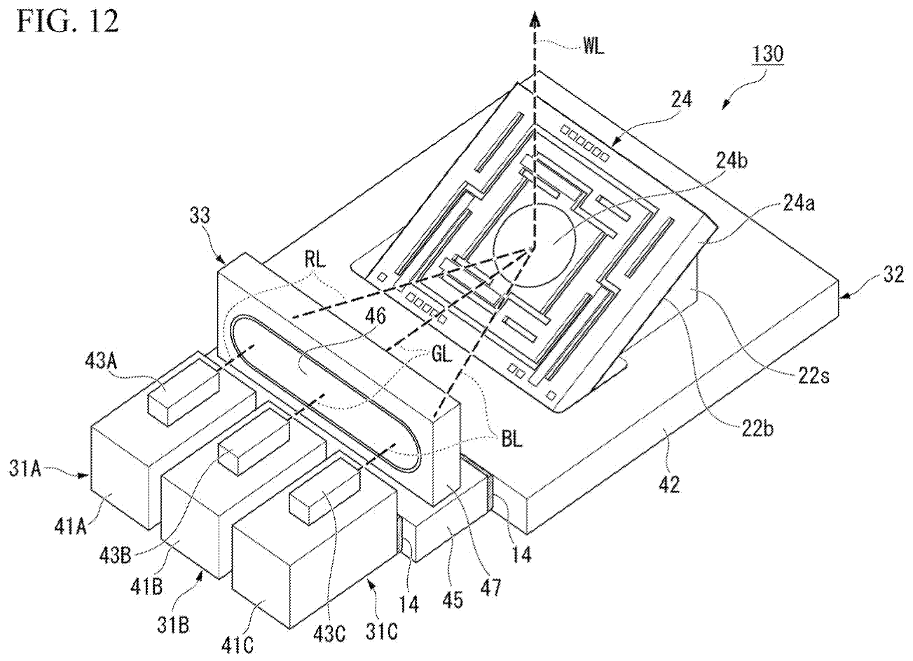

FIG. 12 is an external perspective view showing an optical module according to a second embodiment of the present invention.

The optical module according to the second embodiment differs from the optical module according to the first embodiment in that a lens part is provided between the laser light source part and the mirror part. Components similar to those in the first embodiment are given the same numbers, and redundant explanations will be omitted.

The optical module 130 shown in FIG. 12 includes laser light source parts 31A, 31B, and 31C in which laser light emitting elements 43A, 43B, and 43C are formed on main surfaces of first substrates 41A, 41B, and 41C, a mirror part 32 in which an optical scanning mirror element 24 is formed on a main surface of a second substrate 42, and a lens part 33 in which an optical lens 46 is formed on a main surface of a third substrate 45, the first substrates 41A, 41B, 41C and the third substrate 45 are bonded via a metal bonding layer 14, and laser lights emitted from the laser light emitting elements 43A, 43B, and 43C are reflected by the optical scanning mirror element 24 via the optical lens 46.

The lens part 33 includes a third substrate (subcarrier) 45, an optical lens 46 formed on one main surface 45a of the third substrate 45, and a lens holder 47 that supports the optical lens 46.

The third substrate 45 is configured of a silicon (Si) substrate, an aluminum oxide (Al₂O₃) substrate, an aluminum nitride (AlN) substrate, a quartz (SiO₂) substrate, or the like. The third substrate 45 may be made of the same material as the first substrates 41A, 41B, and 41C on which the laser light source parts 31A, 31B, and 31C are provided, and the second substrate 42 constituting the mirror part 32, and may be made of a different material from the first substrates 41A, 41B, and 41C and the second substrate 42.

The optical lens 46 constituting the lens part 33 is an aspherical lens with an elliptical exterior, and focuses a plurality of laser lights RL, GL, and BL that are incident from mutually different directions toward the center of the mirror surface portion 24b of the optical scanning mirror element 24.

Further, the lens holder 47 is made entirely of silicon, for example, and supports the optical lens 46 in contact with a peripheral edge portion of the optical lens 46.

The laser light source part 11, the lens part 13, and the mirror part 12 that constitute the optical module 130 are arranged in a straight line. Then, the first substrates 41A, 41B, and 41C constituting the laser light source parts 31A, 31B, and 31C and the third substrate 45 on which the lens part 33 is provided, and the third substrate 45 and the second substrate 42 on which the mirror part 32 is provided are respectively directly bonded to each other via the metal bonding layer 14. That is, the laser light source part 11 and the mirror part 12 are integrated by the metal bonding layer 14 with the lens part 13 interposed therebetween, and constitute the optical module 130.

### [Optical Engine for Image Projection]

Next, a configuration of the optical engine for image projection according to an embodiment of the present invention will be described. Although a configuration of the optical engine for image projection including the optical module of the first embodiment will be described below, the optical module of the second embodiment may be provided instead of the optical module of the first embodiment. Components similar to those of the optical module of the first embodiment are given the same numbers, and redundant descriptions will be omitted.

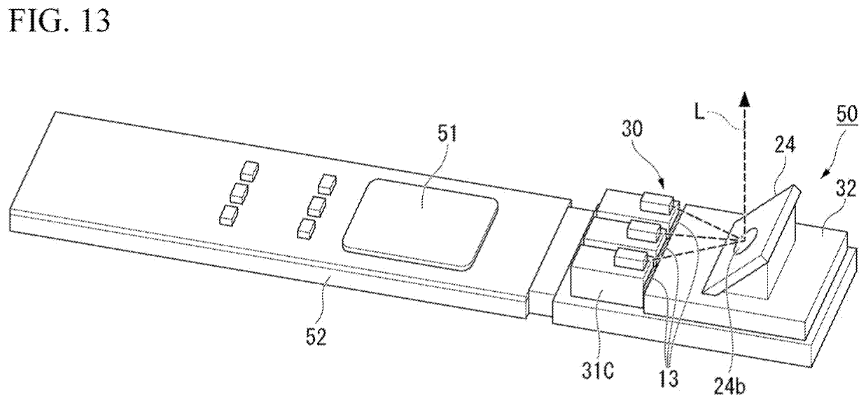

FIG. 13 is an external perspective view showing the optical engine for image projection according to an embodiment of the present invention.

The optical engine 50 for image projection of this embodiment includes the optical module 10 of the first embodiment, an integrated circuit (IC) 51, and a common substrate 52.

The integrated circuit 51 controls light emission of the laser light emitting elements 43A, 43B, and 43C (refer to FIGS. 1 and 2) that constitute the laser light source part 11, and controls an angle of the optical scanning mirror element 24 that constitutes the mirror part 32 (refer to FIGS. 1 and 2).

According to such an optical engine 50 for image projection, it functions as a laser image projection means that is miniaturized and compact. For example, by incorporating such an optical engine 50 for image projection into a wearable device, it is possible to realize a wearable device that can project a clear image while ensuring a comfortable wearing feeling without incompatibility.

### [Glass Display]

Next, the configuration of the optical engine for image projection according to an embodiment of the present invention will be described. Components similar to those of the optical engine for image projection of the embodiment described above are given the same numbers, and redundant descriptions will be omitted.

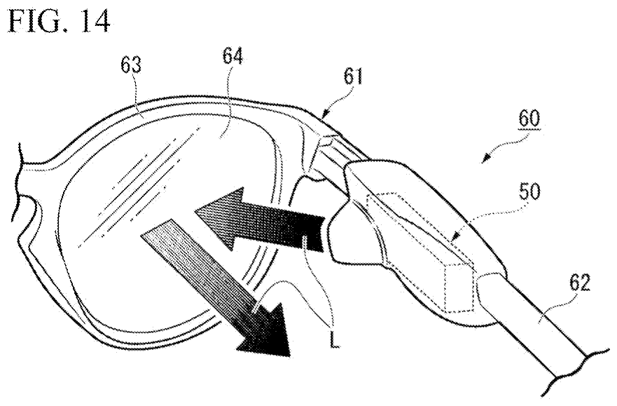

FIG. 14 is an enlarged perspective view of a main portion of a glass display according to the embodiment of the present invention.

The glass display 60 of this embodiment includes the optical engine 50 for image projection of the embodiment described above and a frame 61 having an eyeglass shape.

A miniaturized optical engine 50 for image projection is built in a temple part 62 constituting the frame 61.

The optical engine 50 for image projection emits laser light constituting image light toward a glass 64 supported by a front frame 63 constituting the frame 61. The glass 64 is, for example, a half mirror, and an image formed by the laser light L emitted from the optical engine 50 for image projection is projected onto the glass 64. A wearer of the glass display 60 can directly observe an image projected on an inner surface of the glass 64.

As described above, according to the glass display 60 of this embodiment, it is possible to realize a glass display 60 that maintains a good wearing feeling without greatly expanding the temple part 62 of the frame 61 having an eyeglass shape which has a space limitation using the optical engine 50 for image projection that is compact and lightweight.

### EXPLANATION OF REFERENCES

24 Optical scanning mirror element

30, 130 Optical module

31A, 31B, 31C Laser light source part

32 Mirror part

41A, 41B, 41C First substrate

42 Second substrate

43A, 43B, 43C Laser light emitting element

100 Mirror drive control part

200 Laser drive control part

300 Memory

400 System control part

What is claimed is:

1. An optical module for displaying an image by projecting laser light onto an image display surface, comprising:
a laser light source part provided with a plurality of laser light emitting elements on a main surface of a first substrate, each of the laser light emitting elements being configured to emit each of a plurality of laser lights having different peak wavelengths, respectively;
a mirror part provided with an optical scanning mirror element on a main surface of a second substrate that is integrated with the first substrate;
a laser drive control part configured to individually and independently control an intensity of laser light emitted from the laser light emitting elements;
a mirror drive control part configured to control swinging of the optical scanning mirror element;
a memory configured to store a lookup table that is an array of correspondence relations between each swing position of the optical scanning mirror element and a projection position of each laser light emitted from each of the laser light emitting elements on the image display surface; and
a system control part configured to control the laser drive control part and the mirror drive control part,
wherein the system control part controls the mirror drive control part on a basis of the lookup table.

2. The optical module according to claim 1, wherein the system control part is configured to create a light intensity map table from image data that is a pixel value of each pixel of an image to be displayed on the image display surface and the lookup table and is configured to control the laser drive control part and the mirror drive control part to construct the image on a basis of the light intensity map table, the light intensity map table being an intensity ratio of the laser light emitted from each of the laser light emitting elements for each swing position of the optical scanning mirror element.

3. The optical module according to claim 1, wherein the first substrate and the second substrate are bonded via a metal bonding layer.

4. The optical module according to claim 1, wherein the laser light emitting elements are configured to emit visible light range laser light in a wavelength range of 380 nm or more and less than 800 nm.

5. The optical module according to claim 1, wherein the optical scanning mirror element is a MEMS mirror.

6. The optical module according to claim 1, wherein a surface of a mirror surface portion of the optical scanning mirror element is a concave mirror of which a cross section passing through a center point forms a parabola.

7. An optical engine for image projection, comprising:
the optical module according to claim 1;
one common substrate on which the first substrate and the second substrate are placed; and
an integrated circuit formed on the common substrate and configured to control the laser light emitting element and the optical scanning mirror element.

8. A glass display comprising:
the optical engine for image projection according to claim 7; and
a frame having an eyeglass shape,
wherein the optical engine for image projection is disposed at a temple part of the frame.
